(19) United States
(12) Patent Application Publication
(10) Pub. No.: US 2026/0155795 A1
(43) Pub. Date: Jun. 4, 2026

(54) BIAS COMPENSATION CIRCUITS

(71) Applicant: RichWave Technology Corp., Taipei City (TW)

(72) Inventor: Yi-Fong Wang, Taipei City (TW)

(73) Assignee: RichWave Technology Corp., Taipei City (TW)

(21) Appl. No.: 18/991,655

(22) Filed: Dec. 22, 2024

(30) Foreign Application Priority Data
Nov. 29, 2024 (TW) 113146329

(51) Int. Cl. H03F 3/24; H03F 1/30

(52) U.S. Cl. CPC H03F 3/245; H03F 1/303; H03F 2200/465

(57) ABSTRACT

A bias compensation circuit includes a power detection circuit and a bias circuit. The power detection circuit includes first and second power distribution circuits, first and second detection circuits, first and second conversion circuits, and a summing circuit. The first and second power distribution circuits respectively generate first and second input signals according to an input signal. The first and second detection circuits generate first and second power signals according to first and second input signals, respectively. The first and second conversion circuits generate first and second power currents according to first and second power signals, respectively. The summing circuit receives the first and second power signals to generate a power signal. The bias circuit receives the power signal to adjust a bias signal and provide the bias signal to the amplifier circuit. An amount of variation of the bias signal per power unit is adjustable.

### TECHNICAL FIELD

The present invention relates to radio frequency circuits, and in particular, to bias compensation circuits.

### BACKGROUND

A power amplifier is an electronic circuit designed to amplify the power of an input signal to drive a load or support broader signal transmission. The power amplifier is frequently used in wireless communications and radio frequency transmission. In the related technologies, power amplifiers are still impacted by third-order intermodulation distortion, deteriorating linearity and significantly affecting the efficiency and signal quality of the entire system.

### SUMMARY

According to an embodiment of the invention, a bias compensation circuit providing a bias signal to an amplifier circuit includes a power detection circuit and a bias circuit. The power detection circuit is used to detect a power of the amplifier circuit. The power detection circuit includes an input terminal, an output terminal, a first power allocation circuit, a first detection circuit, a second power allocation circuit, a second detection circuit, and an output circuit. The input terminal is used to receive an input signal of the amplifier circuit. The output terminal is used to output a power signal. The first power allocation circuit is coupled to the input terminal, and is used to generate a first power allocation signal according to the input signal. The first detection circuit is coupled to the first power allocation circuit, and is used to generate a first detection signal according to the first power allocation signal. The second power allocation circuit is coupled to the input terminal or the first power allocation circuit, and is used to generate a second power allocation signal according to the input signal, the second power allocation signal corresponding to a power zone exceeding a power zone of the first power allocation signal. The second detection circuit is coupled to the second power allocation circuit, and is used to generate a second detection signal according to the second power allocation signal. The output circuit is coupled to the first detection circuit and the second detection circuit. The output circuit includes a first conversion circuit, a second conversion circuit, and a combining circuit. The first conversion circuit is used to convert the first detection signal into a first power current. The second conversion circuit is used to convert the second detection signal into a second power current. The combining circuit is coupled to the first conversion circuit and the second conversion circuit, and is used to receive the first power current and the second power current and generate a power signal. The bias circuit is coupled to the output terminal of the power detection circuit, is used to receive the power signal to adjust the bias signal, wherein an amount of variation of the bias signal per power unit is adjustable.

According to another embodiment of the invention, a bias compensation circuit providing a bias signal to an amplifier circuit includes a power detection circuit, a bias circuit and an adjustment circuit. The power detection circuit is used to detect a power of the amplifier circuit. The power detection circuit includes an input terminal, an output terminal, a first power allocation circuit, a first detection circuit, a second power allocation circuit, a second detection circuit, and an output circuit. The input terminal is used to receive an input signal of the amplifier circuit. The output terminal is used to output a power signal. The first power allocation circuit is coupled to the input terminal, and is used to generate a first power allocation signal according to the input signal. The first detection circuit is coupled to the first power allocation circuit, and is used to generate a first detection signal according to the first power allocation signal. The second power allocation circuit is coupled to the input terminal or the first power allocation circuit, and is used to generate a second power allocation signal according to the input signal, the second power allocation signal corresponding to a power zone exceeding a power zone of the first power allocation signal. The second detection circuit is coupled to the second power allocation circuit, and is used to generate a second detection signal according to the second power allocation signal. The output circuit is coupled to the first detection circuit and the second detection circuit. The output circuit includes a first conversion circuit, a second conversion circuit, and a combining circuit. The first conversion circuit is used to convert the first detection signal into a first power current according to a first current gain. The second conversion circuit is used to convert the second detection signal into a second power current according to a second current gain. The combining circuit is coupled to the first conversion circuit and the second conversion circuit, and is used to receive the first power current and the second power current and generate a power signal. The bias circuit is coupled to the output terminal of the power detection circuit, and is used to receive the power signal to adjust the bias signal. The adjustment circuit is used to adjust at least one of impedance of the first power allocation circuit, impedance of the second power allocation circuit, impedance of the first conversion circuit, impedance of the second conversion circuit, the first current gain of the first conversion circuit, and the second current gain of the second conversion circuit.

According to another embodiment of the invention, a bias compensation circuit providing a bias signal to an amplifier circuit includes a power detection circuit, a bias circuit and an adjustment circuit. The power detection circuit is used to detect a power of the amplifier circuit. The power detection circuit includes an input terminal, an output terminal, a power allocation circuit, and a detection circuit. The input terminal is used to receive an input signal of the amplifier circuit. The output terminal is used to output a power signal. The power allocation circuit is coupled to the input terminal, and is used to generate a power allocation signal according to the input signal. The detection circuit is coupled to the power allocation circuit, and is used to generate a detection signal according to the power allocation signal. The bias circuit is coupled to the output terminal of the power detection circuit, and is used to receive a power signal derived from the detection signal to adjust the bias signal, wherein an amount of variation of the bias signal per power unit is adjustable. The adjustment circuit is used to adjust at least impedance of the power allocation circuit.

### BRIEF DESCRIPTION OF THE DRAWINGS

FIG. 1 is a block diagram of a power amplification device according to an embodiment of the invention.

FIG. 2 is a schematic diagram illustrating intermodulation distortion of the power amplifier in FIG. 1.

FIG. 3A is a schematic diagram of the power response of the bias signal in FIG. 1.

FIG. 3B is a schematic diagram of AM-AM linearity of the power amplifier in FIG. 1.

FIG. 4 is a schematic diagram of the attenuator and the power detection circuit in FIG. 1.

FIG. 5 is a circuit schematic of the output circuit in FIG. 1, according to an embodiment of the invention.

FIG. 6 is a circuit schematic of the output circuit in FIG. 1, according to another embodiment of the invention.

FIG. 7 is a circuit schematic of the conversion circuit and the bias circuit in FIG. 1.

FIG. 8 is circuit schematic diagram of the conversion circuit and the bias circuit in FIG. 1, according to another embodiment of the invention.

FIG. 9 is a block diagram of a power amplifier according to another embodiment of the invention.

### DETAILED DESCRIPTION

Below, exemplary embodiments will be described in detail with reference to accompanying drawings so as to be easily realized by a person having ordinary knowledge in the art. The inventive concept may be embodied in various forms without being limited to the embodiments set forth herein. Descriptions of well-known parts are omitted for clarity, and like reference numerals refer to like elements throughout.

In various embodiments of the present invention, the transistors may be bipolar junction transistors (BJTs) or metal-oxide-semiconductor field-effect transistors (MOSFETs). If the transistor is a bipolar junction transistor, the control terminal can be the base, the first terminal can be the collector, and the second terminal can be the emitter. If the transistor is a metal-oxide-semiconductor field-effect transistor, the control terminal can be the gate, the first terminal can be the drain, and the second terminal can be the source.

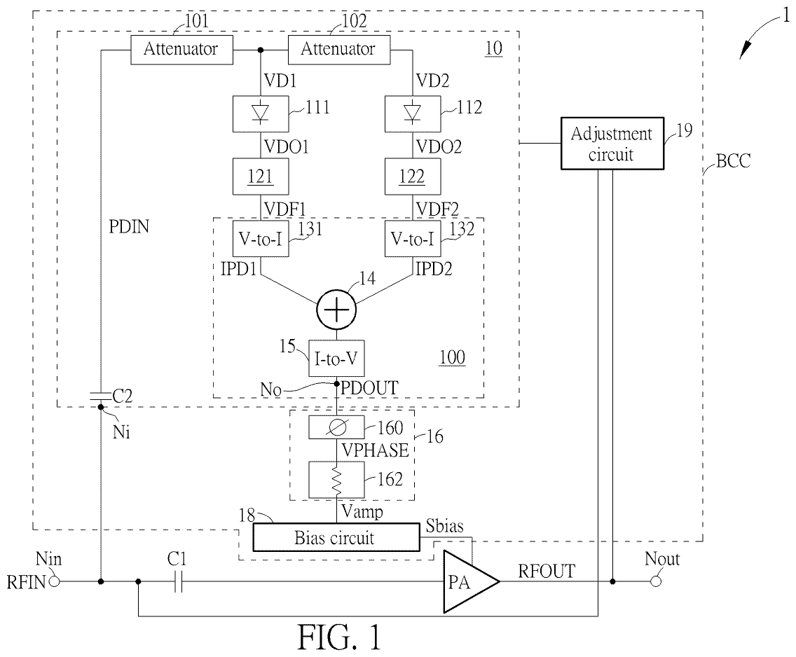

FIG. 1 is a block diagram of a power amplification device 1 according to an embodiment of the invention. The power amplification device 1 may receive an input signal RFIN from an input terminal Nin and amplify the input signal RFIN to generate an output signal RFOUT at an output terminal Nout. Both the input signal RFIN and the output signal RFOUT may be alternating current (AC) voltages, especially radio frequency (RF) voltages. The input signal RFIN may contain two or more AC components. The output signal RFOUT may contain two or more amplified AC components. For clarity, the power amplification device 1 is discussed in the following paragraphs by considering that the input signal RFIN contains the first AC component and the second AC component. The frequency of the second AC component may be greater than the frequency of the first AC component.

The power amplification device 1 may include a bias compensation circuit BCC, a capacitor C1, and a power amplifier (PA, also known as an amplifier circuit). The capacitor C1 may block the DC component in the input signal RFIN, ensuring that the input signal RFIN received by the power amplifier PA only contains AC component. The power amplifier PA may amplify the input signal RFIN to generate the output signal RFOUT. Harmonics are generated when the first and second AC components of the input signal RFIN pass through the power amplifier PA. The harmonics interact with the original first and second AC components, resulting in third-order intermodulation distortion (IMD3), the frequencies of the IMD3 components are related to the frequencies of the first and second AC components, leading to degradation in the quality of the output signal RFOUT.

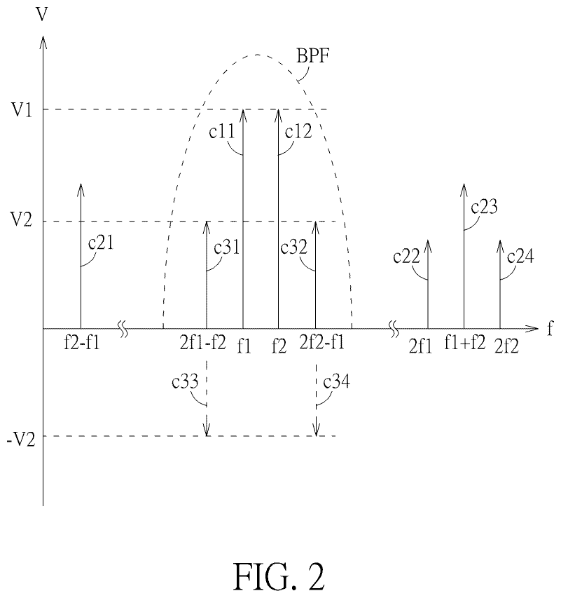

FIG. 2 is a schematic diagram illustrating intermodulation distortion (IMD) of the power amplifier PA, where the horizontal axis represents frequency f and the vertical axis represents voltage V. FIG. 2 shows the AC components in the output signal RFOUT. The AC component c11, being the amplified first AC component, has the frequency f1 and the voltage V1. The AC component c12, being the amplified second AC component, has the frequency f2 and the voltage V1. The AC components c22 and c24 are second order harmonics. The AC components c21 and c23 are generated by the second-order intermodulation distortion (IMD2) of the power amplifier PA. The frequency of the AC component c21 may be (f2−f1), the frequency of the AC component c22 may be 2f1, the frequency of the AC component c23 may be (f1+f2), and the frequency of the AC component c24 may be 2f2. The AC components c31 and c32 are generated by the third-order intermodulation distortion (IMD3) of the power amplifier PA. The AC component c31 may have a frequency of (2f1−f2) and a voltage of V2, while the AC component c32 may have a frequency of (2f2−f1) and a voltage of V2. The AC components c11 and c12 are the desired components in the output signal RFOUT, while the AC components c21 to c24, c31, and c32 are the undesired components in the output signal RFOUT. The AC components c21 to c24 are farther from the AC components c11 and c12 and can be removed using a bandpass filter BPF, while the AC components c31 and c32 are closer to the AC components c11 and c12 and cannot be removed using the bandpass filter BPF.

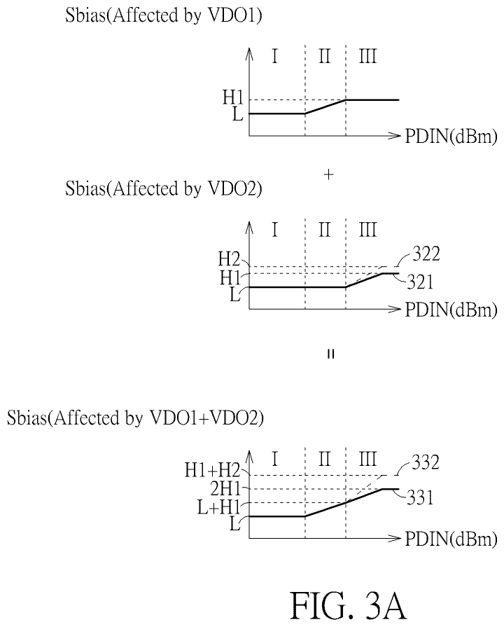

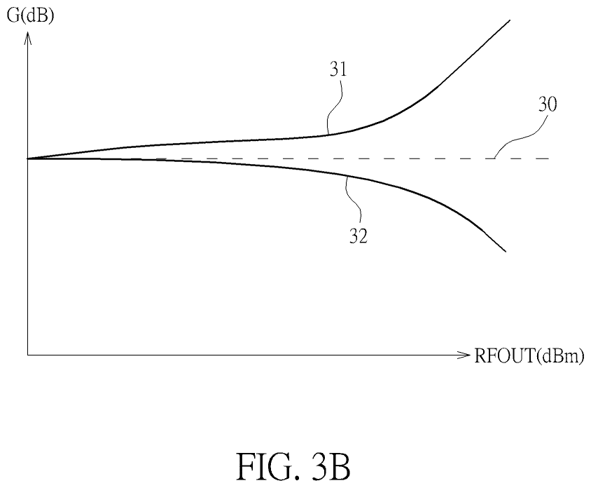

Referring to FIGS. 1 and 2, the bias compensation circuit BCC may detect the power of the input signal RFIN, adjust the bias signal Sbias according to the power of the input signal RFIN, and provide the bias signal Sbias to bias the power amplifier PA. The bias signal Sbias may be a current signal or a voltage signal provided to the power amplifier PA, and the current signal and voltage signal may change in the same direction. The power of the input signal RFIN contains the IMD2 components, resulting in the bias signal Sbias also having the IMD2 components. After the IMD2 components of the bias signal Sbias are adjusted in phase and/or amplitude, the adjusted IMD2 components of the bias signal Sbias may be input to the power amplifier PA and interact with the AC components c11 and c12 to generate the IMD3 AC components c33 and c34. The AC component c33 may have a frequency of (2f1−f2) and a voltage of (−V2), while the AC component c34 may have a frequency of (2f2−f1) and a voltage of (−V2). The AC components c33 and c34 may respectively reduce (e.g., cancel) the AC components c31 and c32, thereby mitigating the IMD3 effect of the power amplifier PA and enhancing the linearity of the power amplifier PA. In addition, the bias compensation circuit BCC may adaptively adjust the variation in the amplitude of the bias signal Sbias per unit power according to the power of the input signal RFIN, further enhancing the linearity of the power amplifier PA, as shown in FIG. 3A, which will be explained in detail in the following paragraphs. In some embodiments, the input terminal Ni of the bias compensation circuit BCC can also be coupled to the output terminal Nout of the power amplifier PA to detect the power of the output signal RFOUT, and then adjust the bias signal Sbias according to the power of the output signal RFOUT. The following discussion focuses on the bias compensation circuit BCC employing the power of the input signal RFIN to adjust the bias signal Sbias.

The bias compensation circuit BCC may include a power detection circuit 10, a conversion circuit 16, a bias circuit 18, and an adjustment circuit 19. In FIG. 1 of In the embodiment, the input terminal Ni of the power detection circuit 10 may be coupled to the input terminal Nin. The conversion circuit 16 may be coupled to the power detection circuit 10. The bias circuit 18 may be coupled to the conversion circuit 16 and the power amplifier PA. The power amplifier PA may be coupled to the adjustment circuit 19.

The power detection circuit 10 may detect the power of the input signal RFIN to generate a power signal PDOUT. The power detection circuit 10 may include the input terminal Ni, an output terminal No, a capacitor C2, an attenuator 101 (first power allocation circuit), a power detector 111 (first detection circuit), a harmonic filter 121, an attenuator 102 (second power allocation circuit), a power detector 112 (second detection circuit), a harmonic filter 122, and an output circuit 100.

The first terminal of the attenuator 101 may be coupled to the input terminal Ni via the capacitor C2, while the first terminal of the attenuator 102 may be coupled to the second terminal of the attenuator 101. The first terminal of the power detector 111 may be coupled to the second terminal of the attenuator 101, while the first terminal of the power detector 112 may be coupled to the second terminal of the attenuator 102. The first terminal of the harmonic filter 121 may be coupled to the second terminal of the power detector 111, while the first terminal of the harmonic filter 122 may be coupled to the second terminal of the power detector 112. The second terminal of the output circuit 100 may be coupled to the second terminal of the harmonic filter 121 and the second terminal of the harmonic filter 122, and the second terminal of the output circuit 100 may be coupled to the output terminal No. In one embodiment, the capacitor C2 may be omitted if necessary, and the attenuator 101 may be directly coupled to the input terminal Ni.

The input terminal Ni of the power detection circuit 10 may receive the input signal RFIN of the power amplifier PA, and the output terminal No may output the power signal PDOUT. The capacitor C2 may block the DC component in the input signal RFIN to generate a radio frequency (RF) signal PDIN, and transmit the RF signal PDIN containing only the AC component to the attenuator 101.

The attenuators 101 and 102 and the power detectors 111 and 112 may detect power in different power zones, thereby enhancing the linearity of the power signal PDOUT. The attenuator 101 may generate a power allocation signal VD1 based on the RF signal PDIN, and then the power detector 111 may generate a detection signal VDO1 based on the power allocation signal VD1. The attenuator 102 may generate a power allocation signal VD2 according to the power allocation signal VD1, and then the power detector 112 may generate a detection signal VDO2 according to the power allocation signal VD2. The attenuators 101 and 102 may sequentially reduce the RF signal PDIN, thereby progressively increasing the attenuation intensity corresponding to the power allocation signals VD1 to VD2. The power allocation signals VD1 and VD2 may correspond to different power zones, where the power zone corresponding to the power allocation signal VD2 may be higher than the power zone corresponding to the power allocation signal VD1. The power detectors 111 and 112 may respectively perform half-wave rectification on the power allocation signals VD1 and VD2 to generate the detection signals VDO1 and VDO2. In some embodiments, both the attenuators 101 and 102 may be directly coupled to the input terminal Ni to directly adjust different attenuations to the RF signal PDIN, so as to generate the power allocation signals VD1 and VD2, respectively. In some embodiments, the attenuators 101 and 102 may further perform impedance matching at the input terminal Ni, ensuring that the power detection circuit 10 generates the power allocation signals VD1 and VD2 without affecting the RF signal PDIN.

The harmonic filters 121 and 122 may be resistor-capacitor (RC) low-pass filters, selectively filtering out harmonic frequencies in the detection signals VDO1 and VDO2 to generate filter voltages VDF1 and VDF2, thereby enhancing the signal quality. In some embodiments, the harmonic filters 121 and 122 may filter out the harmonic components (such as the first harmonic component sin(ωt) and the second harmonic component sin(2ωt), where ω is the fundamental frequency, t is the time in the detection signals VDO1 and VDO2), respectively, so as to generate the filter voltages VDF1 and VDF2. The filter voltages VDF1 and VDF2 may include DC component and AC components. The second-order intermodulation distortion occurs when the power detectors 111 and 112 process the power allocation signals VD1 and VD2, and the harmonic filters 121 and 122 process the detection signals VDO1 and VDO2, resulting in the filter voltages VDF1 and VDF2 containing IMD2 components with a frequency of (f2−f1).

The output circuit 100 may generate the power signal PDOUT based on the filter voltages VDF1 and VDF2 and transmit the power signal PDOUT to the conversion circuit 16. The output circuit 100 may include a voltage-to-current (V-to-I) converter 131 (first conversion circuit), a voltage-to-current converter 132 (second conversion circuit), a current summing node 14, and a current-to-voltage (I-to-V) converter 15. The current summing node 14 and the current-to-voltage conversion circuit 15 may be collectively referred to as an integrated circuit. The voltage-to-current converter 131 may be coupled to the harmonic filter 121 to convert the filter voltage VDF1 into a power detection current IPD1, while the voltage-to-current converter 132 may be coupled to the harmonic filter 122 to convert the filter voltage VDF2 into a power detection current IPD2. The current summing node 14 may be coupled to the voltage-to-current converters 131 and 132 to accumulate the power detection currents IPD1 and IPD2, generating a summed current (IPD1+IPD2). The current-to-voltage converter 15 may be coupled to the current summing node 14 to convert the summed current (IPD1+IPD2) into a summed voltage, generating the power signal PDOUT. In some embodiments, the current-to-voltage conversion circuit 15 may directly output the summed voltage as the power signal PDOUT. In other embodiments, the current-to-voltage conversion circuit 15 may further perform level shift and/or filtering operations on the power signal PDOUT before outputting the resultant signal as the power signal PDOUT.

The power signal PDOUT represents the power of the power amplifier PA. The power signal PDOUT may include both the DC component and AC components, with the DC component corresponding to the power level of the RF signal PDIN, and the AC component corresponding to the IMD2 component at the frequency of (f2−f1). The conversion circuit 16 may adjust the phase and amplitude of the power signal PDOUT to generate the adjustment signal Vamp, the adjustment signal Vamp including the adjusted DC component and the adjusted IMD2 component. The conversion circuit 16 may include a phase shifter 160 and an amplitude controller 162. The phase shifter 160 may be coupled to the current-to-voltage converter 15 to adjust the phase of the power signal PDOUT, generating the phase adjustment voltage VPHASE. In some embodiments, the phase shifter 160 may invert the phase of the power signal PDOUT. The amplitude controller 162 may be coupled to the current-to-voltage converter 15 to adjust the amplitude of the phase adjustment voltage VPHASE to generate the amplitude adjustment signal Vamp.

The bias circuit 18 may be coupled to the conversion circuit 16, and the conversion circuit 16 may be coupled to the output terminal No of the power detection circuit 10, ensuring that the bias circuit 18 adjusts the bias signal Sbias based on the power signal PDOUT. The amount of variation of the bias signal Sbias per power unit may be adjusted based on the power of the output signal RFOUT. The power signal PDOUT includes a phase component or an amplitude component resulting from modulation of the radio frequency signal. The frequencies of the phase component or the amplitude component of the power signal PDOUT are less than the cutoff frequency of the harmonic filters 121 and 122 of the detection circuit 10. Specifically, the bias circuit 18 may receive the amplitude adjustment signal Vamp and generate the bias signal Sbias accordingly. Therefore, the bias signal Sbias includes a DC component and an IMD2 component. The bias circuit 18 may use the bias signal Sbias to bias the power amplifier PA. The power amplifier PA may be biased by the DC component in the bias signal Sbias to linearly amplify the input signal RFIN. The IMD2 components in the bias signal Sbias may enter the power amplifier PA and interact with the original first and second AC components, generating the AC components c33 and c34 as shown in FIG. 2. The AC components c33 and c34 may at least partially cancel out the AC components c31 and c32, reducing the IMD3 effect and enhancing the linearity.

The adjustment circuit 19 may configure the internal components of the power detection circuit 10 based on the output signal RFOUT, or the ratio of the input signal RFIN and the output signal RFOUT, to adjust the sensitivity of the power signal PDOUT in response to variations in the power of the RF signal PDIN. Specifically, the adjustment circuit 19 may adjust the amount of variation of the bias signal Sbias per power unit of the RF signal PDIN based on the ratio of the output signal RFOUT or the input signal RFIN and the output signal RFOUT, that is, the slope of the power signal PDOUT to the power of the RF signal PDIN. The unit of the power signal PDOUT may be volts (V), while the power unit of the RF signal PDIN may be decibel-milliwatts (dBm). The adjustment circuit 19 may control the voltage variations of the power signal PDOUT in response to the power variations of the RF signal PDIN per dBm. Specifically, the adjustment circuit 19 may determine the voltage change when the power of the RF signal PDIN shifts by 1 dBm. The magnitude of the DC component of the power signal PDOUT is positively correlated with the magnitude of the DC component of the bias signal Sbias. The adjustment circuit 19 may determine the performance in the high power zone based on the output signal RFOUT, and increase amount of variation of the bias signal Sbias per power unit of the RF signal PDIN in the high power zone, which subsequently increases the magnitude of the DC component of the bias signal Sbias, thereby enhancing the linearity of the power amplifier PA.

FIG. 3A is a schematic diagram of the power response of the bias signal Sbias, where the horizontal axis represents the power of the RF signal PDIN in dBm, and the vertical axis represents the bias signal Sbias in volt (V) or ampere (ampere, A). FIG. 3A shows a high power zone III, a medium power zone II, and a low power zone I. In the medium power zone II and the high power zone III, the bias signal Sbias may increase linearly as the power of the RF signal PDIN increases. The amount of variation of the bias signal Sbias per power unit in the high power zone III may be adjustable. In some embodiments, the amount of variation of the bias signal Sbias per power unit in the high power zone III is adjusted based on the output signal RFOUT.

When the power of the RF signal PDIN falls within the low power zone I, the bias signal Sbias affected by the detection signal VDO1 may remain at a low level L, and the bias signal Sbias affected by the detection signal VDO2 may also remain at the low level L, resulting in a level 2L of the bias signal Sbias affected by the detection signals VDO1 and VDO2.

When the power of the RF signal PDIN falls within the medium power zone II, the bias signal Sbias affected by the detection signal VDO1 may linearly increase from the low level L to a high level H1 as the power of the RF signal PDIN increases. The bias signal Sbias affected by the detection signal VDO2 may remain at the low level L. During the period, the bias signal Sbias affected by the detection signals VDO1 and VDO2 linearly increasing from 2L to (L+H1) as the detection signal VDO1 increases.

When the power of the RF signal PDIN falls within the high power zone III, the adjustment circuit 19 may select one of the slopes 321 and 322 to generate the bias signal Sbias. If the slope 321 is selected, the bias signal Sbias affected by the detection signal VDO1 may remain at the high level H1, and the bias signal Sbias affected by the detection signal VDO2 may linearly increase from the low level L to the high level H1 as the power of the RF signal PDIN increases. Consequently, the bias signal Sbias affected by the detection signals VDO1 and VDO2 may linearly increase from the level (L+H1) to the level 2H1 as the detection signal VDO2 increases. If the slope 322 is selected, the bias signal Sbias affected by the detection signal VDO1 may be maintained at the high level H1, and the bias signal Sbias affected by the detection signal VDO2 may linearly increase from the low level L to the high level H2 as the power of the RF signal PDIN increases. Consequently, the bias signal Sbias affected by the detection signals VDO1 and VDO2 may linearly increase from the level (L+H1) to the level (H1+H2) as the detection signal VDO2 increases. The high level H2 may be greater than the high level H1, so the slope 332 of the bias signal Sbias affected by the detection signals VDO1 and VDO2 in the high power zone III may be greater than the slope 331 of the maximum current (H1+H2) in the high power zone III. The maximum current is 2H1.

In one embodiment, the adjustment circuit 19 may select one of the slopes 331 and 332 based on the AM-AM (amplitude-to-amplitude modulation) curve of the power amplifier PA, so as to obtain a suitable amount of variation of the bias signal Sbias per power unit.

FIG. 3B is a schematic diagram of AM-AM linearity of the power amplifier PA, where the horizontal axis represents the power of the output signal RFOUT in dBm, and the vertical axis represents the gain G of the power amplifier PA in dB. In FIG. 3B, the curve 30 illustrates that the ideal gain G of the power amplifier PA is a constant that does not change with the power variations of the output signal RFOUT. The curve 31 illustrates that the gain G of the power amplifier PA increases as the power of the output signal RFOUT increases. The adjustment circuit 19 may adjust the bias signal Sbias to the gentler slope 331, for the compensated gain G to remain constant regardless of the power variations of the output signal RFOUT. The curve 32 illustrates that the gain G of the power amplifier PA decreases as the power of the output signal RFOUT increases. The adjustment circuit 19 may adjust the bias signal Sbias to the steeper slope 332, for the compensated gain G to remain constant regardless of the power variations of the output signal RFOUT.

In one embodiment, the adjustment circuit 19 may select one of the slopes 321 and 332 based on be based the output signal RFOUT to obtain a suitable amount of variation of the bias signal Sbias per power unit. Specifically, the adjustment circuit 19 may store an AM-AM curve lookup table of the power amplifier PA, and find the present gain from the AM-AM curve lookup table based on the current power of the output signal RFOUT. If the present gain exceeds the ideal gain, the adjustment circuit 19 may select the gentler slope 331. On the contrary, if the present gain is less than the ideal gain, the adjustment circuit 19 may select the steeper slope 332. In other embodiments, the adjustment circuit 19 may identify and record the power zones of the output signal RFOUT. In some embodiments, the adjustment circuit 19 may determine the high gain zone, which occurs when the gain of the power amplifier PA exceeds the ideal gain, and the low gain zone, which occurs when the gain of the PA falls below the ideal gain. If the current power of the output signal RFOUT falls in the high gain zone, the adjustment circuit 19 may select the gentler slope 331. On the contrary, if the present power falls in the low gain zone, the adjustment circuit 19 may select the steeper slope 332. In other embodiments, the adjustment circuit 19 may select one of the slopes 321 and 332 based on the ratio of input signal RFIN and the output signal RFOUT. Specifically, the adjustment circuit 19 may divide the output signal RFOUT by the input signal RFIN to generate the present gain. If the present gain exceeds the ideal gain, the adjustment circuit 19 may select the gentler slope 331. On the contrary, if the present gain is less than the ideal gain, the adjustment circuit 19 may select the steeper slope 332. The following discussion focuses on the embodiment utilizing an AM-AM curve lookup table within the adjustment circuit 19. While specific examples are presented, the invention is not limited to these examples. Those skilled in the field would recognize and apply alternative methods for slope selection based on the principles of the invention

In some embodiments, if the present gain of the output signal RFOUT power is low (i.e., less than the ideal gain), the adjustment circuit 19 may select the slope 332, increasing the bias signal Sbias to enhance the linearity of the power amplifier PA. The embodiments of the invention are not limited to adjusting the slope of the bias signal Sbias only in the high power zone III, those skilled in the art would recognize that the slopes of the medium power zone II and the low power zone I may be adjusted as needed without deviating from the principle of the invention. Additionally, the number of power zones for the RF signal PDIN is not limited to three and may include other numbers of power zones.

The adjustment circuit 19 may adjust at least one of the impedance of the attenuators 101 and 102, the impedance of the voltage-to-current converters 131 and 132, and the current gain of the voltage-to-current converters 131 and 132 to select either the slope 331 or 332. The bias circuit 18 may also adjust the bias signal Sbias based on the temperature, the reference voltage, the maximum power of the input signal RFIN of the power amplifier PA, the duty cycle of the input signal RFIN of the power amplifier PA, and the modulation type of the input signal RFIN of the power amplifier PA.

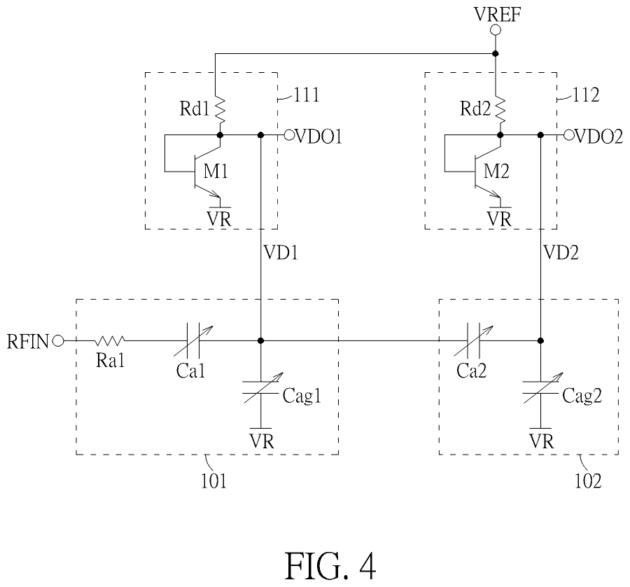

FIG. 4 is a schematic diagram of the attenuators 101 and 102 and the power detection circuits 111 and 112.

The attenuator 101 may include a resistor Ra1, a variable capacitor Ca1, and a variable capacitor Cag1. The resistor Ra1 includes a first terminal coupled to the input terminal Ni, and a second terminal. The variable capacitor Ca1 includes a first terminal coupled to the second terminal of the resistor Ra1, and a second terminal coupled to the power detector 111 and the first terminal of the variable capacitor Ca2. The variable capacitor Cag1 includes a first terminal coupled to the second terminal of the variable capacitor Ca1, and a second terminal coupled to the first reference voltage terminal to receive the reference voltage VR. The reference voltage terminal VR may be a grounding voltage such as 0V.

The attenuator 102 may include a resistor Ra2, a variable capacitor Ca2, and a variable capacitor Cag2. The variable capacitor Ca2 includes a first terminal coupled to the attenuator 101, and a second terminal coupled to the power detector 112. The variable capacitor Cag2 includes a first terminal coupled to the second terminal of the variable capacitor Ca2, and a second terminal coupled to the first reference voltage terminal to receive the reference voltage VR.

The resistor Ra1 may attenuate the RF signal PDIN and increase the input impedance of the power detection device 1. The variable capacitors Ca1 and Ca2 may remove the DC offset error of the attenuators 101 and 102 and only allow the AC components to pass, thereby ensuring the accuracy of the signal. The variable capacitors Cag1 and Cag2 may attenuate the AC component of the RF signal PDIN and adjust the input impedance of the power detection device 1. Since the attenuators 101 and 102 are coupled in series, the attenuators 101 and 102 may attenuate the RF signal PDIN to generate different power allocation signals VD1 and VD2. Meanwhile, the attenuators 101 and 102 may optimize the real and imaginary parts of the RF signal PDIN using resistive components and variable capacitive components, respectively, thereby improving the error vector magnitude (EVM) of the power amplifier, and thus enhancing performance and efficiency.

In some embodiments, if the present gain of the output signal RFOUT is low (i.e., less than the ideal gain), the adjustment circuit 19 may increase the capacitance of the variable capacitor Ca1, so as to enhance the slope of the bias signal Sbias in relation to the change in the power of the RF signal PDIN in the medium power zone II. For instance, the adjustment circuit 19 may select a steeper slope. In other embodiments, if the present gain of the output signal RFOUT is high (i.e., exceeds the ideal gain), the adjustment circuit 19 may reduce the capacitance of the variable capacitor Ca1, so as to reduce the slope of the bias signal Sbias in relation to the change in the power of the RF signal PDIN in the medium power zone II. For instance, the adjustment circuit 19 may select a gentler slope.

In some embodiments, if the present gain of the output signal RFOUT is low, the adjustment circuit 19 may reduce the capacitance of the variable capacitor Cag1, so as to increase the slope of the bias signal Sbias in relation to the change in the power of the RF signal PDIN in the medium power zone II. In such cases, the adjustment circuit 19 may select a steeper slope. In other embodiments, if the present gain of the output signal RFOUT is high, the adjustment circuit 19 may increase the capacitance of the variable capacitor Cag1, so as to reduce the slope of the bias signal Sbias in relation to the change in the power of the RF signal PDIN in the medium power zone II. In such cases, the adjustment circuit 19 may select a gentler slope.

In some embodiments, if the AM-AM curve of the output signal RFOUT is low in the high power zone III, the adjustment circuit 19 may increase the capacitance of the variable capacitor Ca2, so as to enhance the slope of the bias signal Sbias in relation to the change in the power of the RF signal PDIN in the high power zone III. In such cases, the adjustment circuit 19 may select the steeper slope 332 shown in FIG. 3A. In some embodiments, if the AM-AM curve of the output signal RFOUT is high in the high power zone III, the adjustment circuit 19 may decrease the capacitance of the variable capacitor Ca2, so as to reduce the slope of the bias signal Sbias in relation to the change in the power of the RF signal PDIN in the high power zone III. In such cases, the adjustment circuit 19 may select the gentler slope 331 shown in FIG. 3A.

In some embodiments, if the AM-AM curve of the output signal RFOUT is low in the high power zone III, the adjustment circuit 19 may reduce the capacitance of the variable capacitor Cag2, so as to increase the slope of the bias signal Sbias in relation to the change in the power of the RF signal PDIN in the high power zone III. In such cases, the adjustment circuit 19 may select the steeper slope 332 shown in FIG. 3A. In some embodiments, if the AM-AM curve of the output signal RFOUT is high in the high power zone III, the adjustment circuit 19 may increase the capacitance of the variable capacitor Cag2, so as to reduce the slope of the bias signal Sbias in relation to the change in the power of the RF signal PDIN in the high power zone III. In such cases, the adjustment circuit 19 may select the gentler slope 331 shown in FIG. 3A.

In one embodiment, the adjustment circuit 19 may adjust the capacitances of the variable capacitors Ca1, Cag1, Ca2, and/or Cag2 based on the output signal RFOUT, so as to control the amount of variation of the bias signal Sbias per power unit of the RF signal PDIN.

The power detection circuit 111 may include a resistor Rd1 and a transistor M1. The resistor Rd1 includes a first terminal coupled to the second reference voltage terminal and configured to receive the reference voltage VREF, and a second terminal coupled to the first terminal of the variable capacitor Cag1 and configured to receive the power allocation signal VD1 and generate the power detection voltage VDO1. The transistor M1 includes a control terminal; a first terminal coupled to the control terminal of the transistor M1 and the second terminal of the resistor Rd1; and a second terminal coupled to the first reference voltage terminal to receive the reference voltage VR. The reference voltage VREF may be greater than the reference voltage VR, for example, the reference voltage VREF may be 3V.

The power detection circuit 112 may include a resistor Rd2 and a transistor M2. The resistor Rd2 includes a first terminal coupled to the first terminal of the resistor Rd1; and a second terminal coupled to the first terminal of the variable capacitor Cag2 and configured to receive the power allocation signal VD2 and generate the power detection signal voltage VDO2. The transistor M2 includes a control terminal; a first terminal coupled to the control terminal of the transistor M2 and the second terminal of the resistor Rd2; and a second terminal coupled to the first reference voltage terminal to receive the reference voltage VR.

The transistors M1 and M2 may be bipolar transistors or metal oxide semiconductor field effect transistors. The transistors M1 and M2 are configured in the diode form. In some embodiments, the transistors M1 and/or M2 may be replaced by diodes. When the power allocation signal VD1 or VD2 is less than the threshold voltage of the transistor M1 or M2 (for example, 0.7V), the transistor M1 or M2 may be turned off, and the power detection voltage VDO1 or VDO2 may be equal to the power allocation signal VD1 or VD2. When the power allocation signal VD1 or VD2 is greater than or equal to the threshold voltage of the transistor M1 or M2, the transistor M1 or M2 may be turned on, and the power detection voltage VDO1 or VDO2 may be equal to the threshold voltage of the transistor M1 or M2. Therefore, the transistors M1 and M2 may serve as half-wave rectifiers that pass the negative half-wave and block the positive half-wave. In some embodiments, the transistors M1 and M2 may also be configured as half-wave rectifiers that pass the positive half-wave and block the negative half-wave.

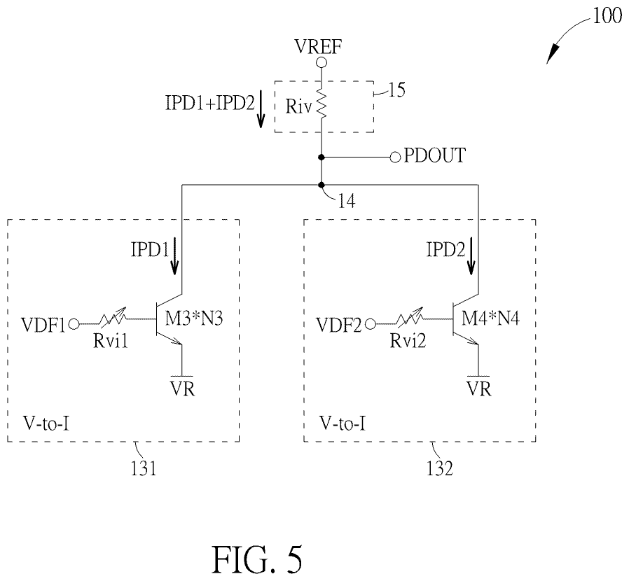

FIG. 5 is a circuit schematic of the output circuit 100 according to an embodiment of the invention.

The voltage-to-current converter 131 may include a variable resistor Rvi1 and a set of transistors M3. The variable resistor Rvi1 includes a first terminal coupled to the power detector 111; and a second terminal. The set of transistors M3 includes a control terminal coupled to the second terminal of the variable resistor Rvi1; a first terminal coupled to the current summing node 14; and a second terminal coupled to the first reference voltage terminal to receive the reference voltage VR. The set of transistors M3 may include N3 transistors M3.

The voltage-to-current conversion circuit 132 may include a variable resistor Rvi2 and a set of transistors M4. The variable resistor Rvi2 includes a first terminal coupled to the power detector 112; and a second terminal. The set of transistors M4 includes a control terminal coupled to the second terminal of the variable resistor Rvi2; a first terminal coupled to the current-to-voltage conversion circuit 15; and a second terminal coupled to the first reference voltage terminal to receive the reference voltage VR. The set of transistors M4 may have N4 transistors M4.

The current-to-voltage conversion circuit 15 may include a resistor Riv. The resistor Riv includes a first terminal and a second terminal. The first terminal is coupled to the second reference voltage terminal configured to receive the reference voltage VREF; the second terminal is coupled to the current summing node 14, configured to generate the power signal PDOUT.

The set of transistors M3 may obtain the control terminal voltage (that is, the filter voltage VDF1) through the variable resistor Rvi1, and draw the power detection current IPD1 from the second reference voltage terminal according to the control terminal voltage of the set of transistors M3. Similarly, the set of transistors M4 may obtain the control terminal voltage (that is, the filter voltage VDF2) through the variable resistor Rvi2, and draw the power detection current IPD2 from the second reference voltage terminal according to the control terminal voltage of the set of transistors M4. Both the power detection currents IPD1 and IPD2 will flow from the second reference voltage terminal via the resistor Riv, and consequently, the power signal PDOUT may be negatively correlated with the sum of the power detection currents IPD1 and IPD2 (IPD1+IPD2). In some embodiments, the current-to-voltage conversion circuit 15 may additionally include a capacitor coupled between the second terminal of the resistor Riv and the first reference voltage terminal to reduce or remove noise in the power signal PDOUT, thereby enhancing the signal quality.

In some embodiments, if the present gain of the output signal RFOUT is low, the resistance of the variable resistor Rvi1 may be decreased, so as to increase the slope of the bias signal Sbias in relation to the change in the power of the RF signal PDIN in the medium power zone II. In such cases, the adjustment circuit 19 may select a steeper slope In other embodiments, if the present gain of the output signal RFOUT is high, the resistance of the variable resistor Rvi1 may be increased, so as to reduce the slope of the bias signal Sbias in relation to the change in the power of the RF signal PDIN in the medium power zone II. In such cases, the adjustment circuit 19 may select a gentler slope

In some embodiments, if the present gain of the output signal RFOUT is low, the adjustment circuit 19 may increase the effective number of the set of parallel-connected transistors M3, so as to enhance the slope of the bias signal Sbias in relation to the change in the power of the RF signal PDIN in the medium power zone II. In such cases, the adjustment circuit 19 may select a steeper slope In other embodiments, if the present gain of the output signal RFOUT is high, the adjustment circuit 19 may decrease the effective number of parallel-connected transistors of the set of transistors M3, so as to reduce the slope of the bias signal Sbias in relation to the change in the power of the RF signal PDIN in the medium power zone II. The maximum effective number of parallel-connected transistors of the set of transistors M3 is N3. In such cases, the adjustment circuit 19 may select a gentler slope.

In some embodiments, if the AM-AM curve of the output signal RFOUT is low in the high power zone III, the adjustment circuit 19 may reduce the resistance of the variable resistor Rvi2, so as to enhance the slope of the bias signal Sbias in relation to the change in the power of the RF signal PDIN in the high power zone III. In such cases, the adjustment circuit 19 may select the steeper slope 332 shown in FIG. 3A. In other embodiments, if the AM-AM curve of the output signal RFOUT is high in the high power zone III, the adjustment circuit 19 may increase the resistance of the variable resistor Rvi2, so as to reduce the slope of the bias signal Sbias in relation to the change in the power of the RF signal PDIN in the high power zone III. In such cases, the adjustment circuit 19 may select the gentler slope 331 shown in FIG. 3A.

In some embodiments, if the AM-AM curve of the output signal RFOUT is low in the high power zone III, the adjustment circuit 19 may increase the effective number of the set of parallel-connected transistors M4, so as to enhance the slope of the bias signal Sbias in relation to the change in the power of the RF signal PDIN in the high power zone III. In such cases, the adjustment circuit 19 may select the steeper slope 332 shown in FIG. 3A. In other embodiments, if the AM-AM curve of the output signal RFOUT is high in the high power zone III, the adjustment circuit 19 may reduce the effective number of the set of parallel-connected transistors M4, so as to reduce the slope of the bias signal Sbias in relation to the change in the power of the RF signal PDIN in the high power zone III. The maximum effective number of parallel-connected transistors of the set of transistors M4 is N4. In such cases, the adjustment circuit 19 may select the gentler slope 331 shown in FIG. 3A.

In one embodiment, the adjustment circuit 19 may adjust the resistance of the variable resistor Rvi1, the resistance of the variable resistor Rvi2, the effective number of parallel-connected transistors of the set of transistors M3 and/or the number of parallel-connected transistors of the set of transistors M4 based on the output signal RFOUT, so as to control the amount of variation of the bias signal Sbias per power unit of the RF signal PDIN.

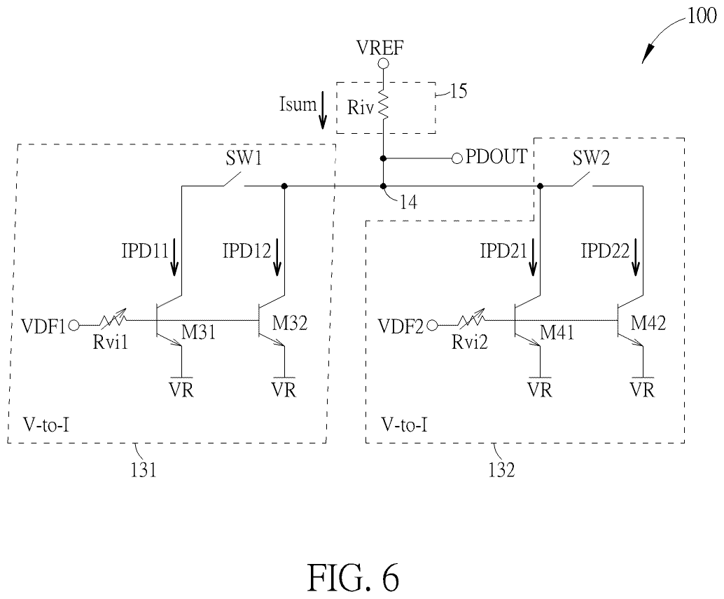

FIG. 6 is a circuit schematic of the output circuit 100 according to another embodiment of the invention.

The voltage-to-current converter 131 may include a variable resistor Rvi1, transistors M31 and M32, and a switch SW1. The variable resistor Rvi1 includes a first terminal coupled to the power detector 111; and a second terminal. The transistor M31 includes a control terminal coupled to the second terminal of the variable resistor Rvi1, a first terminal, and a second terminal coupled to the first reference voltage terminal to receive the reference voltage VR. The transistor M32 includes a control terminal coupled to the second terminal of the variable resistor Rvi1, a first terminal coupled to the current summing node 14, and a second terminal coupled to the first reference voltage terminal to receive the reference voltage VR. The switch SW1 includes a first terminal coupled to the current summing node 14, and a second terminal coupled to the first terminal of the transistor M31.

The voltage-to-current conversion circuit 132 may include a variable resistor Rvi2, transistors M41 and M42, and a switch SW2. The variable resistor Rvi2 includes a first terminal, and a second terminal coupled to the power detector 112. The transistor M41 includes a control terminal coupled to the second terminal of the variable resistor Rvi2, a first terminal coupled to the current summing node 14, and a second terminal coupled to the first reference voltage terminal to receive the reference voltage VR. The transistor M42 includes a control terminal coupled to the second terminal of the variable resistor Rvi2, a first terminal, and a second terminal coupled to the first reference voltage terminal to receive the reference voltage VR. The switch SW2 includes a first terminal coupled to the current-to-voltage conversion circuit 15, and a second terminal coupled to the first terminal of the transistor M42.

The configuration and operation of the current-to-voltage conversion circuit 15 in FIG. 6 are similar to those in FIG. 5. The operations of the variable resistors Rvi1 and Rvi2 in FIG. 6 are similar to those in FIG. 5, and will not be repeated again here for simplicity.

In some embodiments, if the present gain of the output signal RFOUT is low, the switch SW1 may be turned on, enabling the transistor M31 to generate a power detection current IPD11 and the transistor M32 to generate a power detection current IPD12. The summed current Isum is thereby increased, enhancing the slope of the bias signal Sbias in relation to the change in the power of the RF signal PDIN in the medium power zone II. In such cases, the adjustment circuit 19 may select a steeper slope. In other embodiments, if the present gain of the output signal RFOUT is high, the switch SW1 may be turned off, preventing the transistor M31 from generating any current. The summed current Isum is thereby decreased, reducing the slope of the bias signal Sbias in relation to the change in the power of the RF signal PDIN in the medium power zone II. In such cases, the adjustment circuit 19 may select a gentler slope.

In some embodiments, if the present gain of the output signal RFOUT is low, the switch SW2 may be turned on, enabling the transistor M41 to generate a power detection current IPD21 and the transistor M42 to generate a power detection current IPD22. The summed current Isum is thereby increased, enhancing the slope of the bias signal Sbias in relation to the change in the power of the RF signal PDIN in the high power zone III. In such cases, the adjustment circuit 19 may select the steeper slope 332 shown in FIG. 3A. In some embodiments, if the present gain of the output signal RFOUT is high, the switch SW2 may be turned off, preventing the transistor M42 from generating any current. The summed current Isum is thereby decreased, reducing the slope of the bias signal Sbias in relation to the change in the power of the RF signal PDIN in the high power zone III. In such cases, the adjustment circuit 19 may select the gentler slope 321 shown in FIG. 3A.

In one embodiment, the adjustment circuit 19 may adjust the switching state of the switch SW1 or the switching state of the switch SW2 based on the output signal RFOUT to adjust the effective number of parallel-connected transistors, so as to adjust the amount of variation of the bias signal Sbias per power unit of the RF signal PDIN.

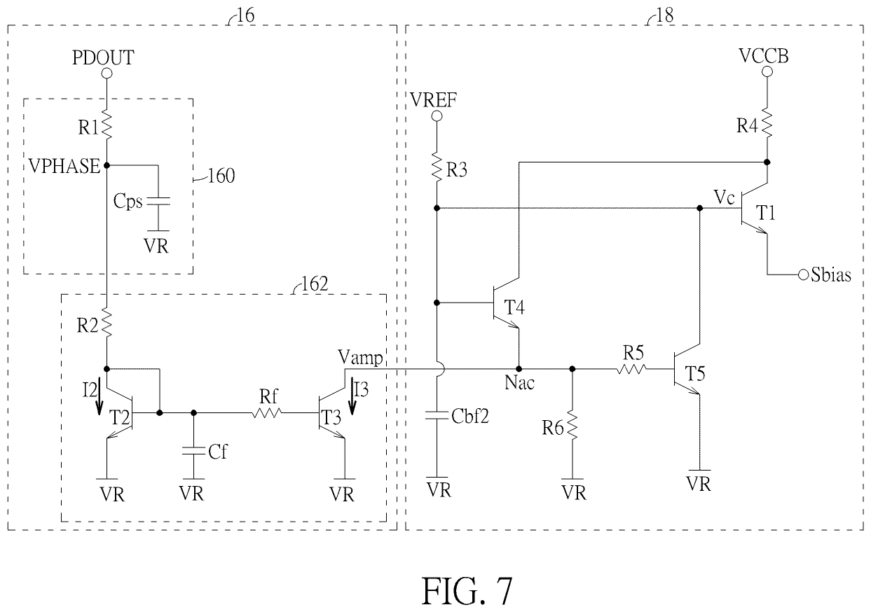

FIG. 7 is a schematic circuit diagram of the conversion circuit 16 and the bias circuit 18. The conversion circuit 16 may adjust the phase and/or amplitude of the power signal PDOUT to generate the injection signal I3. The injection signal I3 may be a current signal. The bias circuit 18 may generate the bias signal Sbias to the power amplifier PA based on the injection signal I3. The bias signal Sbias varies with the power signal PDOUT.

The phase shifter 160 in the conversion circuit 16 may adjust the phase of the power signal PDOUT. The phase shifter 160 may include a resistor R1 and a capacitor Cps. The resistor R1 includes a first terminal coupled to the current-voltage conversion circuit 15 to receive the power signal PDOUT; and a second terminal configured to generate the phase adjustment voltage VPHASE. The capacitor Cps includes a first terminal coupled to the second terminal of the resistor R1; and a second terminal coupled to the first reference voltage terminal to receive the reference voltage VR. The capacitance of the capacitor Cps may affect the phase of the phase adjustment voltage VPHASE.

The amplitude controller 162 in the conversion circuit 16 may adjust the amplitude of the power signal PDOUT. The amplitude controller 162 may be a current mirror circuit to generate the injection signal I3. The amplitude controller 162 may include a resistor R2 and transistors T2 and T3. The transistor T2 may receive the detection current I2. The transistor T3 is coupled to the transistor T2 to generate the injection signal I3. The resistor R2 includes a first terminal coupled to the phase shifter 160 to receive the phase adjustment voltage VPHASE; and a second terminal. The transistor T2 includes a control terminal coupled to the second terminal of the resistor R2; a first terminal coupled to the control terminal of the transistor T2; and a second terminal coupled to the first reference voltage terminal to receive the reference voltage VR. The transistor T3 includes a control terminal coupled to the control terminal of the transistor T2; a first terminal coupled to the bias control node Nac of the bias circuit 18 to generate an amplitude adjustment voltage Vamp; and a second terminal coupled to the first reference voltage terminal to receive the reference voltage VR. The channel widths of the transistors T2 and T3 may be different. In some embodiments, the width of the transistor T2 may be A and the number of fingers may be 1, while the width of the transistor T3 may be A and the number of fingers may be N. In such cases, the effective number of parallel-connected transistors in T2 and T3 may be adjusted to amplify the detection current I2 by a factor of N (the current gain) to generate the injection signal I3, where N is a positive integer greater than 1. The detection current I2 may be positively correlated to the power signal PDOUT. The injection signal I3 may be positively correlated to the detection current I2.

The amplitude controller 162 may further include a resistor Rf and a capacitor Cf. The resistor Rf includes a first terminal coupled to the control terminal of the transistor T2; and a second terminal coupled to the control terminal of the transistor T3. The capacitor Cf includes a first terminal coupled to the first terminal of the resistor Rf; and a second terminal coupled to the first reference voltage terminal to receive the reference voltage VR.

FIG. 7 is a schematic circuit diagram of the conversion circuit 16 and the bias circuit 18. The resistor R2 in the phase shifter 160 and the amplitude controller 162 may be omitted, and the conversion circuit 16 may further include a voltage-to-current conversion circuit to generate the detection current I2 based on the power signal PDOUT. The voltage-to-current conversion circuit includes a first terminal coupled to the detection circuit; and a second terminal coupled to the amplitude controller 162. The amplitude controller 162 may generate the injection signal I3 based on the detection current I2. The voltage-to-current conversion circuit may be, but is not limited to a resistor.

The bias circuit 18 may include a bias transistor T1, transistors T4 and T5, resistors R3 to R6, and a capacitor Cbf2.

The transistor T4 includes a control terminal coupled to the second reference voltage terminal configured to receive the reference voltage VREF; a first terminal coupled to a third reference voltage terminal to receive the reference voltage VCCB; and a second terminal coupled to the conversion circuit 16 via the bias control node Nac.

The transistor T5 includes a control terminal coupled to the second terminal of the transistor T4; a first terminal; and a second terminal coupled to the first reference voltage terminal to receive the reference voltage VR. The reference voltage VCCB may be greater than the reference voltages VREF and VR, for example, the reference voltage VCCB may be 5V. The bias transistor T1 includes a control terminal coupled to the first terminal of the transistor T5; a first terminal coupled to the third reference voltage terminal to receive the reference voltage VCCB; and a second terminal (or referred to as the output terminal) coupled to the power amplifier PA to provide a bias voltage Vbias and a bias signal Sbias, where the bias signal Sbias varies with the power signal PDOUT. The size of the transistor T4 may be less than the size of the bias transistor T1 to maintain efficiency and save circuit area. In one embodiment, the size of the transistor may be the effective number of parallel-connected transistors. For instance, the size of the transistor T4 may be B1 and the effective number of parallel-connected transistors may be 1, and the size of the transistor T1 may be B2 and the effective number of parallel-connected transistors may be 5.

The resistor R3 includes a first terminal and a second terminal. The first terminal of the resistor R3 is coupled to the second reference voltage terminal to receive the reference voltage VREF, and the second terminal of the resistor R3 is coupled to the control terminal of the transistor T4. The resistor R4 includes a first terminal coupled to the third reference voltage terminal to receive the reference voltage VCCB; and a second terminal coupled to the first terminal of the bias transistor T1. The resistor R5 includes a first terminal coupled to the second terminal of the transistor T2 (T3); and a second terminal coupled to the control terminal of the transistor T5. The resistor R6 includes a first terminal the first terminal of the resistor R5; and a second terminal coupled to the first reference voltage terminal to receive the reference voltage VR. The capacitor Cbf2 includes a first terminal control terminal of the transistor T4; and a second terminal coupled to the first reference voltage terminal to receive the reference voltage VR.

When the power signal PDOUT increases, the detection current I2 and the injection signal I3 also increase, resulting in a decrease in the amplitude adjustment voltage Vamp at the bias control node Nac. The decreased voltage at the bias control node Nac would reduce the conductance of the transistor T5, consequently lowering the current flowing through the transistor T5. As the current flowing through the transistor T5 decreases, the voltage across the resistor R3 also decreases, leading to an increase in voltage at the control terminal of the bias transistor T1. The increased voltage at the control terminal of the bias transistor T1 results in an increase in the conductance of the bias transistor T1, leading to an increase in the bias signal Sbias. Consequently, the bias voltage Vbias rises, which subsequently causes the bias current Ibias to increase.

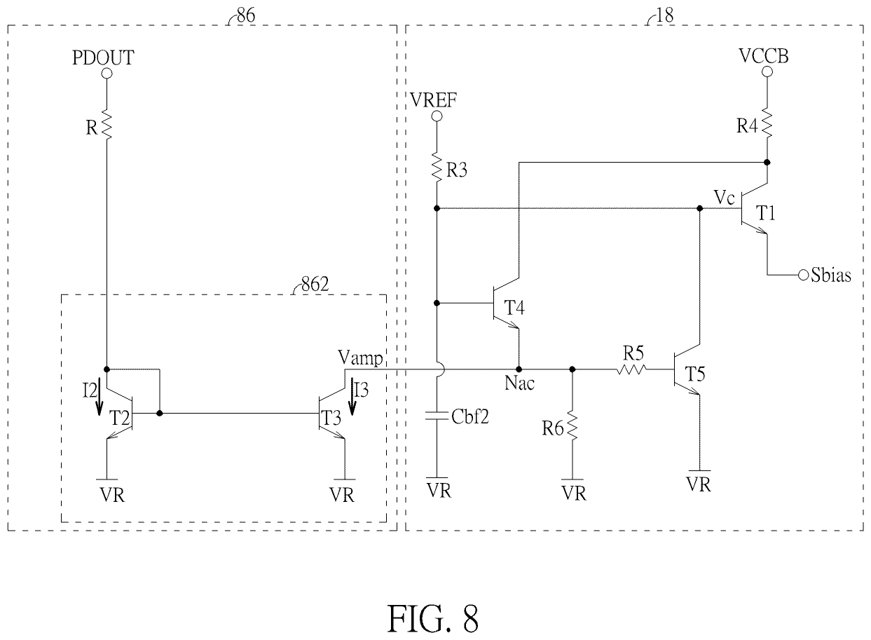

FIG. 8 is a schematic circuit diagram of a conversion circuit 86 and the bias circuit 18. The bias circuits 18 in FIG. 8 and FIG. 7 are identical, so the explanation therefor will not be repeated here. The conversion circuit 86 in FIG. 8 may replace the conversion circuit 16 in FIG. 7. The conversion circuit 86 will be explained as follows.

The resistance of the resistor R in the conversion circuit 86 may be identical to or different from the resistance of the resistor R1 in the conversion circuit 16 to adjust the amplitude of the power signal PDOUT. Compared to conversion circuit 16, the conversion circuit 86 does not include the capacitor Cps and, therefore, does not adjust the phase of the power signal PDOUT. Moreover, the amplitude controller 862 does not contain the capacitor Cf and the resistor Rf, and therefore, the conversion circuit 86 does not perform filtering. Since the conversion circuit 86 does not include the capacitor Cps, capacitor Cf, or resistor Rf, the conversion circuit 86 occupies a smaller circuit area compared to the conversion circuit 16.

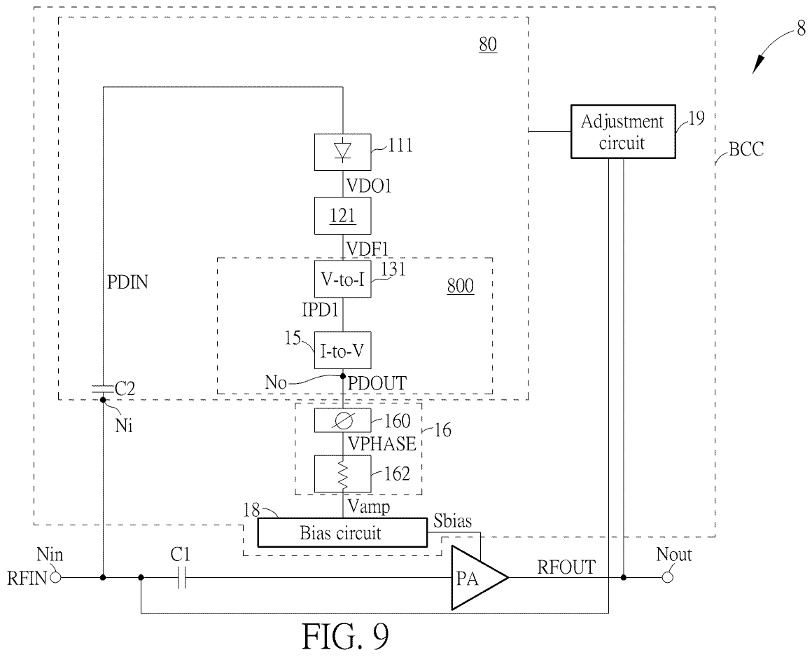

FIG. 9 is a block diagram of a power amplification device according to another embodiment of the invention. The power amplification device 8 is similar to the power amplification device 1, except that the power detection circuit 80 includes a single attenuator 101 and a single power detector 111, and the output circuit 800 includes a single voltage-to-current converter 131 and does not include the current summing node 14. The adjustment circuit 19 may adjust at least one of the impedance of the power allocation circuit, the impedance of the conversion circuit 16, and the current gain of the conversion circuit 16. The power amplification device 8 may reduce the IMD3 effect and improve the linearity according to the operating principle of the power amplification device 1. In some embodiments, the power detection circuit 80 may omit the output circuit 800 (for example, using the filter voltage VDF1 as the power signal PDOUT), provided the frequency of the phase or amplitude component of the power signal PDOUT is below the cutoff frequency of the harmonic filtering device 121.

The power amplification device described in this embodiment employs a bias compensation circuit to reduce the AC components c33 and c34, thereby canceling out IMD3. Additionally, the power amplification device adaptively adjusts the bias signal Sbias according to the power of the input signal RFIN, further reducing the IMD3 effect and improving the linearity of the power amplifier PA.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A bias compensation circuit providing a bias signal to an amplifier circuit, the bias compensation circuit comprising:
a power detection circuit configured to detect a power of the amplifier circuit, the power detection circuit comprising:
an input terminal configured to receive an input signal of the amplifier circuit;
an output terminal configured to output a power signal;
a first power allocation circuit coupled to the input terminal, configured to generate a first power allocation signal according to the input signal;
a first detection circuit coupled to the first power allocation circuit, configured to generate a first detection signal according to the first power allocation signal;
a second power allocation circuit coupled to the input terminal or the first power allocation circuit, configured to generate a second power allocation signal according to the input signal, the second power allocation signal corresponding to a power zone exceeding a power zone of the first power allocation signal;
a second detection circuit coupled to the second power allocation circuit, configured to generate a second detection signal according to the second power allocation signal; and
an output circuit coupled to the first detection circuit and the second detection circuit, the output circuit comprising:
a first conversion circuit configured to convert the first detection signal into a first power current;
a second conversion circuit configured to convert the second detection signal into a second power current; and
a combining circuit coupled to the first conversion circuit and the second conversion circuit, configured to receive the first power current and the second power current and generate a power signal; and
a bias circuit coupled to the output terminal of the power detection circuit, configured to receive the power signal to adjust the bias signal, wherein an amount of variation of the bias signal per power unit is adjustable.

2. The bias compensation circuit of claim 1, wherein the second power allocation circuit comprises:
a first variable capacitor comprising a first terminal coupled to the first power allocation circuit; and a second terminal coupled to the second power detection circuit; and
a second variable capacitor comprising a first terminal coupled to the second terminal of the first variable capacitor; and a second terminal coupled to a first reference voltage terminal;
wherein the amount of variation of the bias signal per power unit is adjusted based on first capacitance of the first variable capacitor or second capacitance of the second variable capacitor.

3. The bias compensation circuit of claim 2, wherein the first power allocation circuit comprises:
a resistor comprising a first terminal coupled to the input terminal; and a second terminal;
a third variable capacitor comprising a first terminal coupled to the second terminal of the resistor; and a second terminal coupled to the first power detection circuit and the first terminal of the first variable capacitor; and
a fourth variable capacitor comprising a first terminal coupled to the second terminal of the third variable capacitor; and a second terminal coupled to the first reference voltage terminal;
wherein the amount of variation of the bias signal per power unit is adjusted based on third capacitance of the third variable capacitor or fourth capacitance of the fourth variable capacitor.

4. The bias compensation circuit of claim 3, further comprising:
an adjustment circuit coupled to the amplifier circuit, configured to adjust one of the first capacitance, the second capacitance, the third capacitance, and the fourth capacitance based on the output signal to adjust the amount of variation of the bias signal per power unit.

5. The bias compensation circuit of claim 1, wherein the first conversion circuit comprises:
a first variable resistor comprising a first terminal coupled to the first detection circuit; and a second terminal; and
a first transistor comprising a control terminal coupled to the second terminal of the first variable resistor; a first terminal coupled to the combining circuit; and a second terminal coupled to a first reference voltage terminal;
wherein the amount of variation of the bias signal per power unit is adjusted based on first resistance of the first variable resistor.

6. The bias compensation circuit of claim 5, wherein the second conversion circuit comprises:
a variable resistor comprising a first terminal coupled to the second detection circuit; and a second terminal; and
a second transistor comprising a control terminal coupled to the second terminal of the variable resistor; a first terminal coupled to the combining circuit; and a second terminal coupled to a first reference voltage terminal;
wherein the amount of variation of the bias signal per power unit is adjusted based on second resistance of the variable resistor.

7. The bias compensation circuit of claim 6, further comprising:
an adjustment circuit coupled to the amplifier circuit, configured to adjust the first resistance or the second resistance based on the output signal to adjust the amount of variation of the bias signal per power unit.

8. The bias compensation circuit of claim 1, wherein the second conversion circuit comprises:
a variable resistor comprising a first terminal coupled to the second detection circuit; and a second terminal;
a second transistor comprising a control terminal coupled to the second terminal of the variable resistor; a first terminal; and a second terminal coupled to a first reference voltage terminal;
a fourth transistor comprising a control terminal coupled to the second terminal of the variable resistor; a first terminal; and a second terminal coupled to the first reference voltage terminal; and
a second switch comprising a first terminal coupled to the combining circuit; and a second terminal coupled to the first terminal of the fourth transistor;
wherein the amount of variation of the bias signal per power unit is adjusted based on a second switching state of the second switch.

9. The bias compensation circuit of claim 8, wherein the first conversion circuit comprises:
a first variable resistor comprising a first terminal coupled to the first detection circuit; and a second terminal;
a first transistor comprising a control terminal coupled to the second terminal of the first variable resistor; a first terminal; and a second terminal coupled to the first reference voltage terminal;
a third transistor comprising a control terminal coupled to the second terminal of the first variable resistor; a first terminal; and a second terminal coupled to the first reference voltage terminal; and
a first switch comprising a first terminal coupled to the combining circuit; and a second terminal coupled to the first terminal of the third transistor;
wherein the amount of variation of the bias signal per power unit is adjusted based on a first switching state of the first switch.

10. The bias compensation circuit of claim 9, further comprising:
an adjustment circuit coupled to the amplifier circuit, configured to adjust the first switching state or the second switching state based on the output signal to adjust the amount of variation of the bias signal per power unit.

11. The bias compensation circuit of claim 1, wherein the power detection circuit further comprises a phase shifter coupled to the output circuit, configured to adjust a phase of the power signal.

12. The bias compensation circuit of claim 11, wherein the phase shifter inverse a phase of the power signal.

13. The bias compensation circuit of claim 11, wherein the phase shifter comprises:
a resistor comprising a first terminal coupled to the combining circuit, and a second terminal; and
a capacitor comprising the second terminal coupled to the resistor, and a second terminal coupled to a first reference voltage terminal.

14. The bias compensation circuit of claim 11, wherein the phase detection circuit further comprises an amplifier controller coupled to the output circuit, configured to adjust an amplitude of the power signal.

15. The bias compensation circuit of claim 14, wherein the amplifier shifter comprises:
a resistor comprising a first terminal coupled to the phase shifter, and a second terminal;
a first transistor comprising a control terminal coupled to the second terminal of the resistor; a first terminal coupled to the control terminal of the first transistor; and a second terminal coupled to a first reference voltage terminal; and
a second transistor comprising a control terminal coupled to the control terminal of the first transistor; a first terminal coupled to the bias circuit; and a second terminal coupled to the first reference voltage terminal.

16. The bias compensation circuit of claim 15, wherein the amplifier shifter further comprises:
a filter resistor comprising a first terminal coupled to the control terminal of the first transistor, and a second terminal coupled to the control terminal of the second transistor; and
a filter capacitor comprising a first terminal coupled to the first terminal of the filter resistor, and a second terminal coupled to the first reference voltage terminal.

17. The bias compensation circuit of claim 1, wherein the input signal is an input signal or the output signal of the amplifier circuit.

18. A bias compensation circuit providing a bias signal to an amplifier circuit, the bias compensation circuit comprising:
a power detection circuit configured to detect a power of the amplifier circuit, the power detection circuit comprising:
an input terminal configured to receive an input signal of the amplifier circuit;
an output terminal configured to output a power signal;
a first power allocation circuit coupled to the input terminal, configured to generate a first power allocation signal according to the input signal;
a first detection circuit coupled to the first power allocation circuit, configured to generate a first detection signal according to the first power allocation signal;
a second power allocation circuit coupled to the input terminal, configured to receive the first detection signal, and generate a second power allocation signal according to the input signal, the second power allocation signal corresponding to a power zone exceeding a power zone of the first power allocation signal;
a second detection circuit coupled to the second power allocation circuit, configured to generate a second detection signal according to the second power allocation signal;
an output circuit coupled to the first detection circuit and the second detection circuit, the output circuit comprising:
a first conversion circuit configured to convert the first detection signal into a first power current according to a first current gain;
a second conversion circuit configured to convert the second detection signal into a second power current according to a second current gain; and
a combining circuit coupled to the first conversion circuit and the second conversion circuit, configured to receive the first power current and the second power current and generate a power signal;
a bias circuit coupled to the output terminal of the power detection circuit, configured to receive the power signal to adjust the bias signal; and
an adjustment circuit configured to adjust at least one of impedance of the first power allocation circuit, impedance of the second power allocation circuit, impedance of the first conversion circuit, impedance of the second conversion circuit, the first current gain of the first conversion circuit, and the second current gain of the second conversion circuit.

19. A bias compensation circuit providing a bias signal to an amplifier circuit, the bias compensation circuit comprising:
a power detection circuit configured to detect a power of the amplifier circuit, the power detection circuit comprising:
an input terminal configured to receive an input signal of the amplifier circuit;
an output terminal configured to output a power signal;
a power allocation circuit coupled to the input terminal, configured to generate a power allocation signal according to the input signal; and
a detection circuit coupled to the power allocation circuit, configured to generate a detection signal according to the power allocation signal;
a bias circuit coupled to the output terminal of the power detection circuit, configured to receive a power signal derived from the detection signal to adjust the bias signal, wherein an amount of variation of the bias signal per power unit is adjustable; and
an adjustment circuit configured to adjust at least impedance of the power allocation circuit.

20. The bias compensation circuit of claim 19, wherein the bias circuit adjusts the bias signal according to a temperature, a reference voltage, a maximal power of an input signal of the amplifier circuit, a duty cycle of the input signal of the amplifier circuit, and a modulation type of the input signal of the amplifier circuit.
